(19) United States
(12) Patent Application Publication
(10) Pub. No.: US 2009/0250793 A1
(43) Pub. Date: Oct. 8, 2009

(54) BPSG FILM DEPOSITION WITH UNDOPED CAPPING

(76) Inventor: Yuri Sokolov, Sandy, UT (US)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/099,348

(22) Filed: Apr. 8, 2008

(51) Int. Cl. H01L 23/58; H01L 21/31

(52) U.S. Cl. 257/636; 438/787; 257/E23.001; 257/E21.24

(57) ABSTRACT

Semiconductor devices containing a CVD BPSG layer and an undoped CVD oxide cap layer are described. The cap layer can be any silicon oxide material with a thickness between about 50 Å and about 350 Å. The cap layer may be formed using a low temperature CVD process that is controlled for density by adjusting the amount of silicon precursor in the gas-phase. In some embodiments, the cap layer is deposited on the BPSG layer followed immediately by the BPSG film deposition prior to any annealing of the BPSG layer. The cap layer may prevent dopant out-diffusion and/or out-gassing during storage and high-temperature annealing, and moisture penetration into the BPSG layer, as well as suppress defect nucleation on the as-deposited BPSG surface and defect formation during high temperature annealing, while still allowing flow ability of the BPSG layer. Other embodiments are also described.

### FIELD

This application relates generally to semiconductor devices and methods of making electronic components for semiconductor devices. In particular, this application relates to methods of depositing borophosphosilicate glass (BPSG) film on a substrate and depositing an undoped capping layer on the BPSG film during the process of making semiconductor devices and the semiconductor devices resulting from those methods.

### BACKGROUND

Borophosphosilicate glass (BPSG) films are used extensively in semiconductor device manufacturing. In some instances, BPSG films are used as dielectric layers for various purposes, including protecting the underlying silicon substrate and the conductive paths in semiconductor device. BPSG films are usually created by various forms of chemical vapor deposition (CVD). Some examples CVD processes include plasma enhanced chemical vapor deposition (PECVD), atmospheric pressure chemical vapor deposition (APCVD), sub-atmospheric pressure chemical vapor deposition (SACVD), high-density plasma chemical vapor deposition (HDP-CVD), and/or low pressure chemical vapor deposition (LPCVD).

Due to specific CVD deposition process, the as-deposited BPSG films are unstable and consequently subjected to high temperature annealing for flow (step coverage), densification, and further stabilization. Flow capability of the film is enhanced by higher dopant concentration in the BPSG. However, other unwanted effects, such as appearance of phosphorus- and/or boron-related defect and dopant out-diffusion may occur during heating the films. Therefore, the requirement of high flow ability at the expense of dopant concentration in the film can contradict the ability to obtain defect free BPSG film.

PECVD processes for making BPSG films hold certain manufacturing and other advantages, and therefore are widely used. However, PECVD BPSG dielectric films are often much more unstable when compared to the thermal LPCVD or other non-plasma CVD films. For this reason, devices that use PECVD BPSG layers are more susceptive to dielectric defect appearance, dopant out-diffusion, and counterdoping than LPCVD.

The BPSG film instability and the unwanted effects, such as appearance of phosphorus- and/or boron-related defects and dopant out-diffusion are associated with moisture absorption into BPSG films that are exposed to ambient air before densification. Also, boron (B) and phosphorus (P) dopants are known to out-diffuse especially at their higher concentrations and with presence of water in the subsurface of the BPSG film. Some methods therefore form a protective layer (or cap) on the BPSG film, preferably using a nitride or a low temperature oxide (LTO). But attempts to anneal the BPSG film with the cap layer often resulted in improper flow of the BPSG film.

### SUMMARY

This application is related to semiconductor devices containing a CVD BPSG layer along with an undoped CVD oxide cap layer. The cap layer can be any silicon oxide material with a thickness between about 50 Å up to about 350 Å. The cap layer may be formed using a low temperature CVD process that is controlled for density by adjusting the amount of SiH₄. In some embodiments, the cap layer is deposited on the BPSG layer in the same run as the BPSG deposited prior to any annealing of the BPSG layer. The cap layer may prevent dopant out-diffusion and/or out-gassing during storage and high-temperature annealing, as well as the defect formation on the BPSG surface due to stopping moisture introduction into the BPSG layer, while still allowing flowability of the BPSG layer.

### BRIEF DESCRIPTION OF THE DRAWINGS

The following description can be better understood in light of the Figures, in which:

FIG. 1 illustrates a cross-sectional view of some embodiments of a semiconductor device containing a substrate with a BPSG layer and cap layer; and

FIG. 2 illustrates a cross-sectional view of other embodiments of an electronic device containing a substrate with a BPSG layer and cap layer.

The Figures illustrate specific aspects of semiconductor devices and associated methods of making and using such devices. Together with the following description, the Figures demonstrate and explain the principles of utilizing the BPSG layer in the semiconductor devices and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the devices and associated methods of using the apparatus can be implemented and used without employing these specific details. Indeed, the devices and associated methods can be placed into practice by modifying the illustrated devices and associated methods and can be used in conjunction with any other apparatus and techniques conventionally used in the industry. For example, while the description below focuses on processes for semiconductor devices in the IC industry, it could be used for and applied to other electronic devices like optoelectronic devices, solar cells, or MEMS structures that contain a dielectric layer component. As well, while the description below focuses on silicon oxide cap layers, it could be modified to add use silicon oxynitride cap layers.

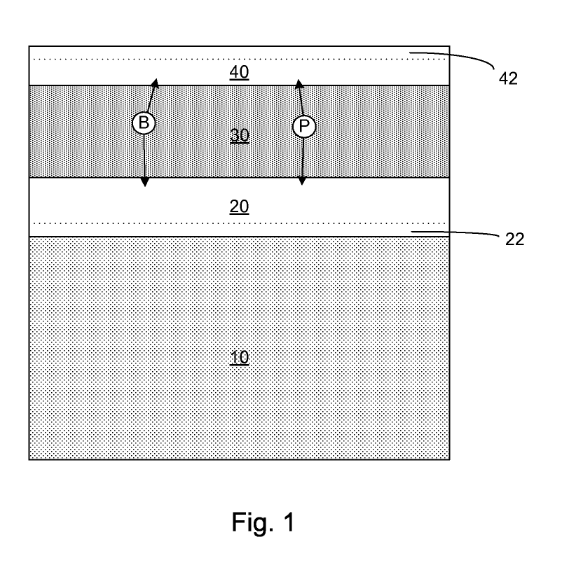

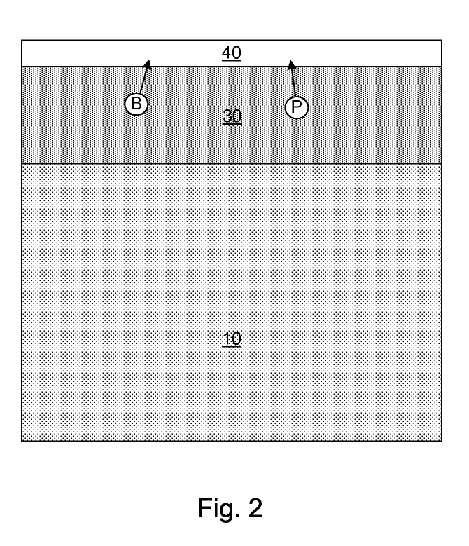

Exemplary semiconductor devices formed using the methods described herein are illustrated in FIGS. 1 and 2. In FIG. 1, the semiconductor device includes a substrate 10, a first layer 20, a doped oxide layer 30, and a cap layer 40. The substrate 10 may comprises any semiconductor material. Some non-limiting examples of semiconductor materials may include silicon (Si), gallium arsenide, germanium, Si—Ge, and the like. In some embodiments, the substrate 10 comprises a silicon substrate.

The first layer 20 may be a low temperature oxide (LTO) layer, such as SiOₓ. The LTO layer may be formed by any known deposition or oxidation method. In some embodiments, such as where the substrate comprises Si, the LTO oxide layer is formed by CVD processes where silicon precursors react with oxygen and other dopant precursors. In some embodiments, the thickness of the LTO layer 20 can range from about 400 Å to about 3000 Å. In other embodiments, any other dielectric layer like thermal oxide, silicon nitride, etc. can be used as first layer 20.

The doped layer 30 may be any dielectric layer containing B and/or P, including BPSG/PSG/BSG layers. In some embodiments, the doped layer 30 may be deposited on the substrate 10 or first layer 20 using any CVD process until the desired thickness (ranging from about 0.1 um to about 20 um) is obtained. Examples of the CVD processes include one or more of PECVD, APCVD, SACVD, LPCVD, HDPCVD, or their combinations. In some embodiments, the BPSG layer is deposited using PECVD until a thickness of about 3000 to about 10000 Å is obtained.

The cap layer 40 may be any oxide-containing dielectric layer, like a low temperature (LTO) layer, such as SiOₓ or silicon oxynitride. The LTO oxide layer may be formed by any known deposition method. In some embodiments, the cap layer 40 is formed by any CVD process in atmosphere of a silicon precursor (like for example SiH₄) with oxidizer until the desired thickness is obtained. In other embodiments, the CVD process used to form the BPSG layer 30 and the subsequent CVD process used to form the cap layer 40 may be done in the same CVD process, with different compounds being made available in the CVD process to produce the BPSG doped layer 30 and then right after, the undoped oxide cap layer 40.

The density of the LTO layer 40 may be controlled as needed. In some instances, the density is controlled during deposition by providing Si-rich to O-rich film composition, thereby controlling the viscosity and water absorbability properties in cap layer 40. The density of the LTO cap layer 40 may be controlled using any known method, including by controlling the silicon/oxygen ratio during the CVD process to increase the Si amount since a Si-rich oxide layer is denser. For example, the density of the SiOₓ material in the cap layer 40 may be controlled by adjusting the SiH₄ gas concentration during the deposition. Increasing the SiH₄ concentration results in making the undoped oxide layer denser and, therefore, serves as both a better barrier to the dopant penetration from the BPSG doped layer 30 and to moisture absorption from the air through the cap layer 40 and into the BPSG doped layer 30. The density of the SiOₓ material in the cap layer 40 may be also controlled by adjusting the deposition process parameters such as pressure, temperature, etc.

The LTO cap layer 40 has to be thin enough so that it does not deteriorate the flow capability of the BPSG doped layer 30. At the same time, the LTO cap layer has to be thick enough to prevent or reduce the out-diffusion of the dopants in the doped layer 30 through the cap layer 40. In some embodiments, the cap layer 40 may have a thickness between about 50 Å and about 350 Å. In other embodiments, the cap layer 40 may have a thickness between about 150 Å and about 300 Å. In yet other embodiments, the cap layer 40 may have a thickness of about 250 Å. The effective thickness of the LTO cap layer will depend, in part, on the B and/or P concentration in the BPSG film and on the annealing conditions applied to the given BPSG film (annealing temperature, pressure, wet/dry atmosphere, etc.)

In some embodiments, the thickness of the cap layer can be about 150 Å and less. In these embodiments, an undoped cap layer 40 may be effective enough to preserve the BPSG doped layer 30 from B and P loss during storage at room temperature. Also, in these embodiments, a thin undoped cap layer 40 prevents appearance of B- and/or P-related defects/nuclei on the as-deposited BPSG film and their development during room temperature storage. In addition, such a thickness may stop moisture absorption from the ambient air into BPSG doped layer 30 which can be helpful since reduced moisture absorption may reduce defect development on the surface of the as-deposited films and since moisture is known as a catalyst for formation of B- and/or P-related defects.

In certain instances, the flow capability of the BPSG doped layer 30 with a thin undoped cap layer 40 which thickness does not exceed of about 150 Å may still be the same as without a cap layer 40. In such instances, a thin cap layer 40 may still be readily autodoped from the BPSG during high temperature annealing. So while a thin cap layer 40 of about 150 Å and less may not prevent dopant outgassing and defect formation at high temperature in these instances, it can still maintain preservative effects at lower temperatures (such as preventing moisture absorption to BPSG doped layer 30).

In some embodiments, the thickness of the cap layer can be larger than about 150 Å. If the cap layer is still less than or about of about 250 Å thick, some defects can appear on the surface of the BPSG layer after annealing because of diffusion of the B and P dopants through the LTO cap layer 40.

In other embodiments, the cap layer 40 may have a thickness ranging from about 250 to about 300 Å. Such a thickness may enhance the benefits of thinner cap layer 40 (with a thickness of about 150 Å) and the benefits of a thicker cap layer 40 (with a thickness up to about 350 Å) that are described herein. With a thickness of about 250 Å, the cap layer 40 may decrease out-gassing of dopants during high temperature annealing that leads to suppression of defect formation on the BPSG surface, while maintaining moisture resistance and flow ability with minimal or no defect formation.

In some embodiments, the thickness of the cap layer can be up to about 350 Å. With a thickness of about 350 Å and more, the cap layer 40 may degrade the flow ability of the underlying BPSG doped layer 30 during subsequent annealing processes because of the poor flow characteristics of the undoped LTO cap layer 40. But if the cap layer 40 thicknesses is only up to about 300 Å, most of the layer 40 will be doped and yet still flow.

During annealing, and as shown in FIG. 1, the cap layer 40 may be infused with B and P dopants that diffuse out of BPSG doped layer 30. Such an infusion relieves the surface tension of the LTO cap layer 40. As illustrated in FIG. 1, the section 42 of the cap layer 40 may represent a portion of the cap layer 40 that remains substantially undoped, even after annealing, as the diffusion may not extend throughout the entire thickness of the cap layer 40. The dopants B and P become less concentrated the further the distance away from the doped layer 30.

The amount of the undoped portion 42 can depend on the thickness of the LTO cap layer 40 and the annealing conditions. Where the cap layer 40 has a thickness between about 200 Å and about 300 Å, and the annealing temperature does not exceed about 950° C., the diffusion from BPSG doped layer 30 may extend into the cap layer 40 up to about 200 Å. For example, in some embodiments, the B can diffuse into the LTO cap layer 40 up to about 150 Å when an annealing process performed at 950° C. for 20 minutes (even allowing for porous SiO₂ with H₂ present). Boron is a prime dopant that enhances flow ability of the BPSG film. P dopant diffuses more slowly, so for the same annealing process, the P dopes the LTO cap in a depth less than about 150 Å.

The dopant transition from the BPSG doped layer 30 to the LTO cap layer 40 may extend anywhere up to 200 Å. In some embodiments, this transition region may have a thickness of about 100 Å to about 200 Å. Thus, where the LTO cap layer 40 has a thickness less than about 200 Å, it may be fully doped and may flow like the BPSG doped layer during certain annealing processes. And if the cap layer 40 thickness is up to about 300 Å, it can be substantially doped and still flow in certain annealing processes. Yet where the cap layer 42 is not completely doped with the B and P dopants, the remaining undoped layer 42 may operate as an elastic thin layer on a flowing BPSG film and does not deteriorate film's flow ability during certain annealing processes.

Similarly, the first layer 20 may also be infused with B and P dopants that diffuse out of BPSG doped layer 30. As illustrated in FIG. 1, the section 22 of the first layer 20 represents a portion of first layer 20 that remains substantially undoped, as diffusion may not extend throughout the entire thickness of the first layer 20. The dopants B and P become less concentrated the further the distances away from the interface between the doped layer 30 and the layer 20.

FIG. 2 illustrates other embodiments where an electronic device contains a silicon substrate 10, doped layer 30, and cap layer 40. Similar to the semiconductor device illustrated in FIG. 1, doped layer 30 may be a BPSG layer deposited with CVD, and cap layer 40 may be an LTO deposited with CVD on doped layer 30. But unlike the device illustrated in FIG. 1, there exists no LTO first layer 20. The configurations of the device illustrated in FIG. 2 can be useful where there is little concern with out-diffusion of the B and/or P dopants into the underlying substrate 10, such as with MEMS structures.

Once the LTO cap layer 40 is deposited on the BPSG doped layer 30, and as described above, one or more annealing processes can be performed. The annealing processes can be performed at a temperature ranging from about 800° C. to about 1000° C. In some embodiments, the annealing processes can be performed at a temperature ranging from about 850 to about 950° C.

After the cap layer 40 and annealing processes have been performed to either of the structure illustrated in FIG. 1 or 2, conventional processing can continue to finish the semiconductor devices. For example, this conventional semiconductor processing can include formation of transistors, formation of metal lines, and final packaging processes. The BPSG doped layer 30 and the LTO cap layer 40 can be used in any semiconductor device in which BPSG films are known to be used.

The use of the cap layer 40 described above upholds the BPSG stability and enables a lower flow temperature to be used in subsequent processing after thin film deposition. As well, when the above thickness are used for the cap layer 40, optical microscopy shows that the integrity of the oxide cap layer was maintained since no oxide cracks were noticed after annealing. Further, the LTO cap layer 40 may provide protection to BPSG doped layer 30 to resist out-diffusion and/or out-gassing of B and P dopants during storage and annealing while also preserving the flowability of the BPSG doped layer 30. The use of the cap layer 40 also reduces BPO₄ defects nucleated in the as-deposited film and during the film densification due to suppression of dopants that appear on the surface. The use of the cap layer 40 can also reduce and/or prevent BPSG film degradation, improvement the metrology of dopants in the BPSG films, and reduce metal degradation due to abolition of phosphoric/boric acids on the BPSG surface.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method of manufacturing a dielectric component for an electronic device, comprising:
providing a substrate;
depositing a dielectric layer containing B or P on the substrate using CVD; and
depositing an undoped oxide-containing cap on the second dielectric layer, wherein the oxide-containing cap has a thickness between about 50 Å and about 350 Å.

2. The method of claim 1, wherein the oxide-containing cap has a thickness between about 150 Å and about 300 Å.

3. The method of claim 1, wherein the oxide-containing cap has a thickness of about 250 Å.

4. The method of claim 1, further comprising depositing the oxide-containing cap substantially immediately following the deposition of the dielectric layer.

5. The method of claim 1, wherein the CVD used to deposit the dielectric layer comprises PECVD, LPCVD, APCVD, HDPCVD, or SACVD.

6. The method of claim 1, wherein the dielectric layer is a BPSG layer and the oxide-containing cap is a SiOₓ layer.

7. The method of claim 1, further comprising annealing the resulting structure.

8. The method of claim 7, wherein the oxide-containing cap reduces out-gassing and out-diffusion of the B and P dopants from the dielectric layer during the annealing process.

9. The method of claim 7, wherein the part of the oxide-containing cap becomes doped during the annealing process.

10. The method of claim 9, wherein about 100 Å to about 200 Å of the oxide-containing cap becomes doped during the annealing process.

11. A method of manufacturing a dielectric component for an electronic device, comprising:
providing a Si substrate;
forming a first dielectric layer on the substrate;
depositing a second dielectric layer containing B or P on the first dielectric layer using PECVD;
depositing an undoped oxide-containing cap on the second dielectric layer, wherein the oxide-containing cap has a thickness between about 50 Å and about 350 Å; and
annealing the resulting structure.

12. The method of claim 11, wherein the oxide-containing cap has a thickness between about 150 Å and about 300 Å.

13. The method of claim 11, wherein the oxide-containing cap has a thickness of about 250 Å.

14. The method of claim 11, wherein the second dielectric layer is a BPSG layer and the oxide-containing cap is a SiO layer.

15. The method of claim 11, wherein about 100 Å to about 200 Å of the oxide-containing cap becomes doped during the annealing process.

16. A dielectric component for an electronic device made by the method comprising:
providing a Si substrate;
forming a first dielectric layer on the substrate;
depositing a second dielectric layer containing B or P on the first dielectric layer using PECVD;
depositing an undoped oxide-containing cap on the second dielectric layer, wherein the oxide-containing cap has a thickness between about 50 Å and about 350 Å; and
annealing the resulting structure.

17. The device of claim 16, wherein the oxide-containing cap has a thickness between about 150 Å and about 300 Å.

18. The device of claim 16, wherein the oxide-containing cap has a thickness of about 250 Å.

19. The device of claim 16, wherein the second dielectric layer is a BPSG layer and the oxide-containing cap is a SiOₓ layer.

20. The device of claim 16, wherein about 100 Å to about 200 Å of the oxide-containing cap becomes doped during the annealing process.

21. An electronic device containing a dielectric component, the device comprising:
a Si substrate;
a PECVD BPSG layer on the substrate; and
an undoped, low temperature SiOₓ cap deposited on the BPSG layer, wherein the oxide cap has a thickness between about 50 Å and about 350 Å.

22. The device of claim 21, wherein the SiOₓ cap has a thickness between about 150 Å and about 300 Å.

23. The device of claim 21, wherein the SiOₓ cap has a thickness of about 250 Å.

24. The device of claim 21, wherein the SiOₓ cap is configured to allow flowability of the BPSG layer and prevent out-gassing and out-diffusion of the B and P dopants from the BPSG layer during annealing.

25. The device of claim 21, further comprising an oxide layer located between the substrate and the BPSG layer.
